(19) United States
(12) Patent Application Publication
(10) Pub. No.: US 2025/0038110 A1
(43) Pub. Date: Jan. 30, 2025

(54) INTEGRATED CIRCUIT DEVICES

(71) Applicant: Samsung Electronics Co., Ltd., Suwon-si (KR)

(72) Inventors: Sangjine Park, Suwon-si (KR); Youngtae Kim, Suwon-si (KR); Ilyoung Yoon, Suwon-si (KR)

(21) Appl. No.: 18/663,344

(22) Filed: May 14, 2024

(30) Foreign Application Priority Data
Jul. 28, 2023 (KR) 10-2023-0098889

(51) Int. Cl. H01L 23/528; H01L 29/06; H01L 29/40; H01L 29/417; H01L 29/423; H01L 29/66; H01L 29/775

(52) U.S. Cl. CPC H01L 23/5286; H01L 29/0673; H01L 29/401; H01L 29/41733; H01L 29/42392; H01L 29/66439; H01L 29/66545; H01L 29/775

(57) ABSTRACT

An integrated circuit device includes a substrate having a front side and a back side opposite to the front side and including a fin-type active region in the front side and a substrate recess in the back side, an isolation film in the substrate defining the fin-type active region, a source/drain region on the fin-type active region, a contact plug above the substrate, a backside power rail at least partially filling the substrate recess, and a via power rail electrically connected to the contact plug, the via power rail extending into the isolation film and connected to the backside power rail. A side surface of the backside power rail and a side surface of the via power rail form an obtuse angle at a portion where the backside power rail is connected to the via power rail.

### CROSS-REFERENCE TO RELATED APPLICATION(S)

This application is based on and claims priority under 35 U.S.C. § 119 to Korean Patent Application No. 10-2023-0098889, filed on Jul. 28, 2023, in the Korean Intellectual Property Office, the disclosure of which is incorporated by reference herein in its entirety.

### BACKGROUND

The inventive concept relates generally to integrated circuit devices, and more particularly, to integrated circuit devices having a power delivery network (PDN).

With the development of electronics technology, down-scaling of integrated circuit devices has been in rapid progress. To efficiently transmit power to integrated circuit devices having high integration density, integrated circuit devices having a PDN are being introduced.

### SUMMARY

The inventive concept provides integrated circuit devices having therein a power delivery network capable of reliably transmitting power to highly integrated elements thereof.

According to an aspect of the inventive concept, there is provided an integrated circuit device including a substrate having a front side and a back side opposite to the front side and including a fin-type active region in the front side and a substrate recess in the back side, an isolation film in the substrate defining the fin-type active region, a source/drain region on the fin-type active region, a contact plug above the substrate, a backside power rail at least partially filling the substrate recess, and a via power rail electrically connected to the contact plug, the via power rail passing through the isolation film and being connected to the backside power rail. A side surface of the backside power rail and a side surface of the via power rail form an obtuse angle at a portion where the backside power rail is connected to the via power rail.

According to another aspect of the inventive concept, there is provided an integrated circuit device including a substrate having a front side and a back side opposite to the front side and including a fin-type active region in the front side and a substrate recess in the back side, an isolation film in the substrate defining the fin-type active region, a source/drain region on the fin-type active region, an intergate insulating layer on the substrate and surrounding (i.e., extending around) the source/drain region, a contact plug passing through at least a portion of the intergate insulating layer and connected to the source/drain region, a backside power rail at least partially filling the substrate recess, a via power rail passing through a portion of the intergate insulating layer and the isolation film and connected to the backside power rail, and a via contact on the contact plug and the via power rail and connecting the contact plug to the via power rail. A side surface of the backside power rail and a side surface of the via power rail form an obtuse angle at a portion where the backside power rail is connected to the via power rail, and the backside power rail is in contact with a lower side surface and a bottom surface of the via power rail.

According to a further aspect of the inventive concept, there is provided an integrated circuit device including a substrate having a front side and a back side opposite to the front side and including a fin-type active region in the front side and a substrate recess in the back side, the fin-type active region extending in a first horizontal direction parallel to an upper surface of the substrate, an isolation film in the substrate defining the fin-type active region, a backside power rail at least partially filling the substrate recess and including a round side surface bulging toward the substrate and the isolation film, a plurality of gate electrodes on the fin-type active region and extending in a second horizontal direction in parallel with each other, the second horizontal direction crossing (i.e., intersecting) the first horizontal direction, a source/drain region on the fin-type active region and between a pair of gate electrodes adjacent to each other in the first horizontal direction among the plurality of gate electrodes, an intergate insulating layer at least partially filling a space between the plurality of gate electrodes and surrounding the source/drain region, a contact plug passing through at least a portion of the intergate insulating layer and being connected to the source/drain region, a via power rail passing through a portion of the intergate insulating layer and the isolation film and being connected to the backside power rail, a cover insulating layer surrounding the via power rail, and a via contact on the contact plug and the via power rail and connecting the contact plug to the via power rail. A side surface of the backside power rail and a side surface of the via power rail form an obtuse angle at a portion where the backside power rail is connected to the via power rail, and the backside power rail includes a wedge portion extending between the via power rail and the cover insulating layer and has a symmetrical structure in a horizontal direction with respect to a center of a bottom surface of the via power rail.

### BRIEF DESCRIPTION OF THE DRAWINGS

Embodiments will be more clearly understood from the following detailed description taken in conjunction with the accompanying drawings, wherein like reference numerals (when used) indicate corresponding elements throughout the several views, and in which:

FIGS. 1A to 13 are cross-sectional views of intermediate process stages in an example method of manufacturing an integrated circuit device, according to one or more embodiments;

FIGS. 14A and 14B are cross-sectional views of an integrated circuit device according to embodiments;

FIGS. 15 to 17 are cross-sectional views illustrating an example method of manufacturing an integrated circuit device, according to one or more embodiments;

FIG. 18 is a cross-sectional view illustrating an example method of manufacturing an integrated circuit device, according to one or more embodiments; and

FIGS. 19A and 19B are cross-sectional views of an integrated circuit device according to embodiments.

### DETAILED DESCRIPTION

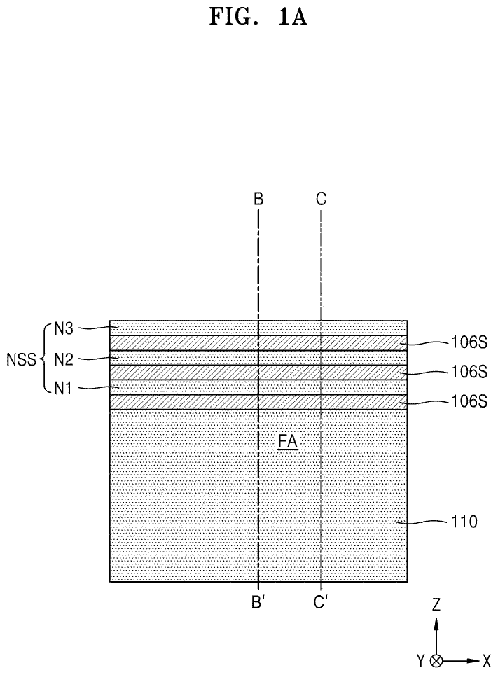

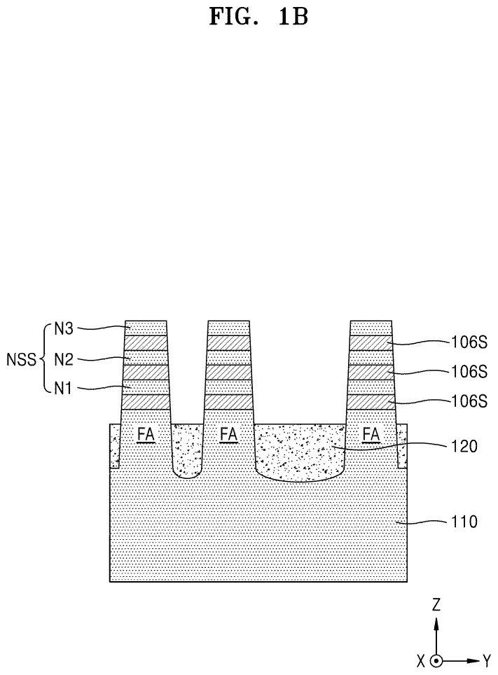

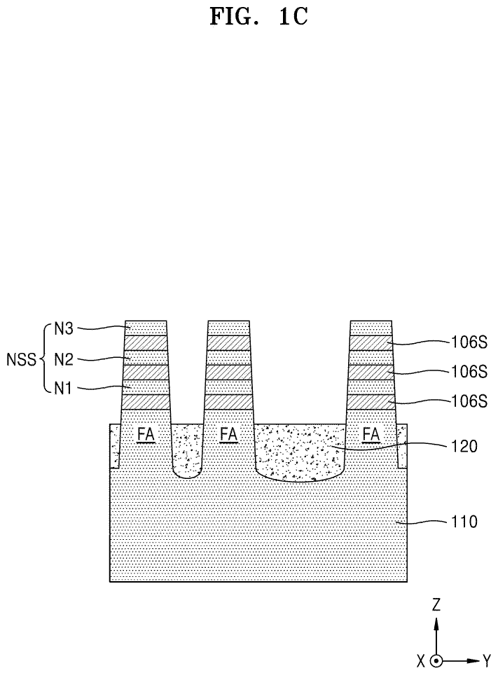

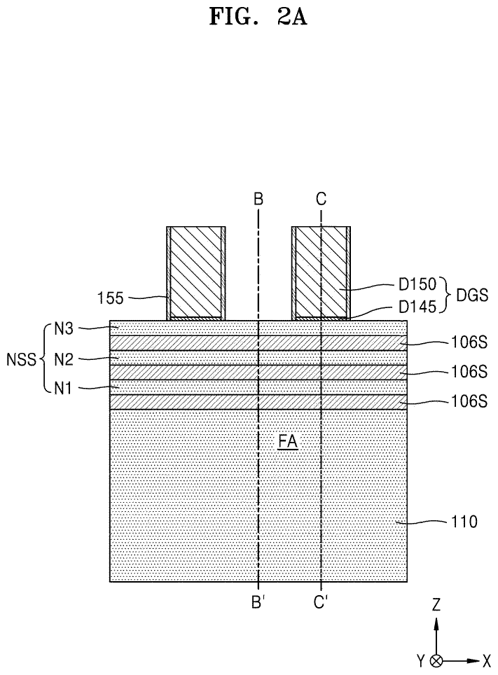

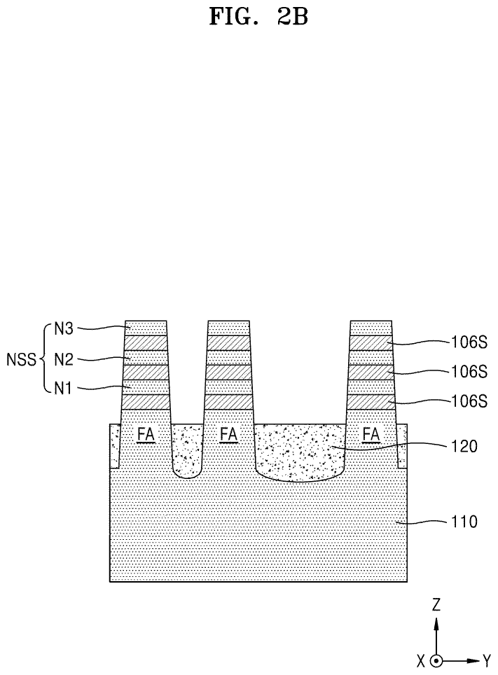

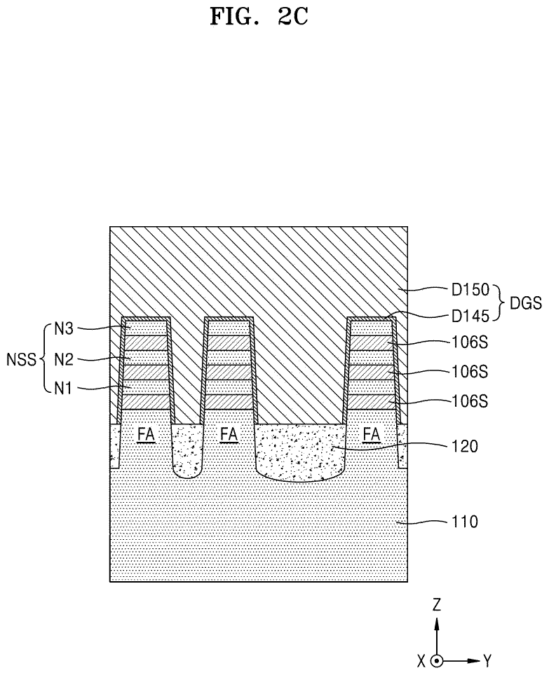

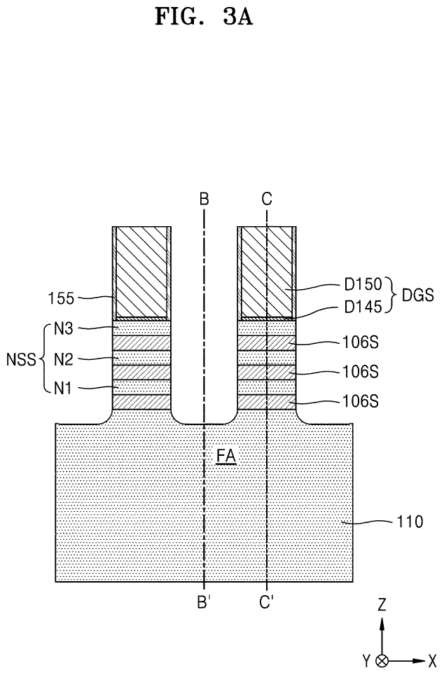

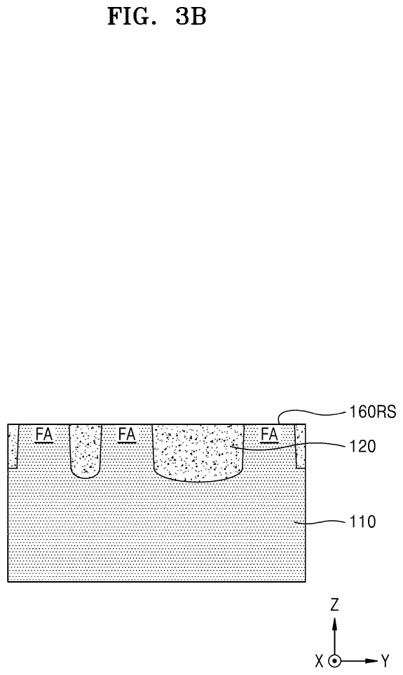

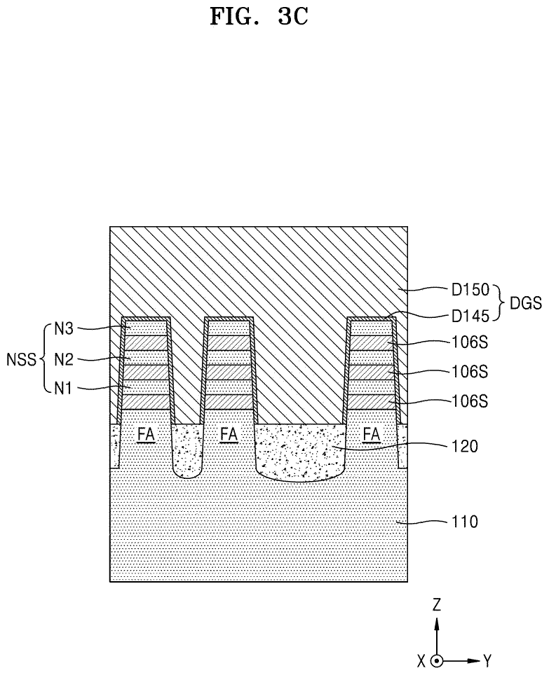

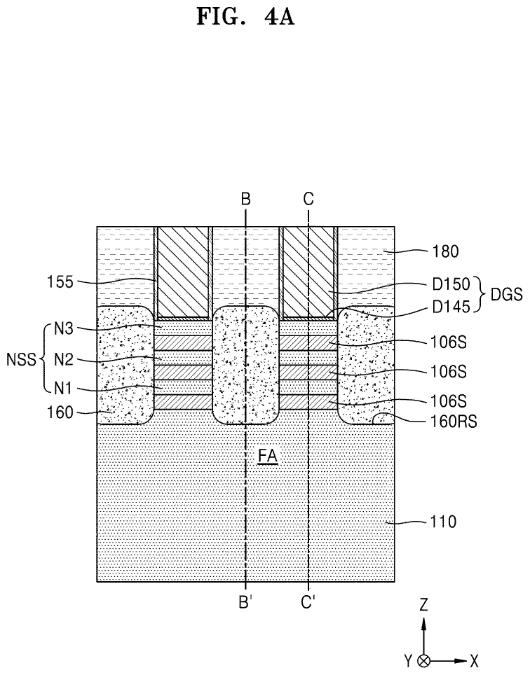

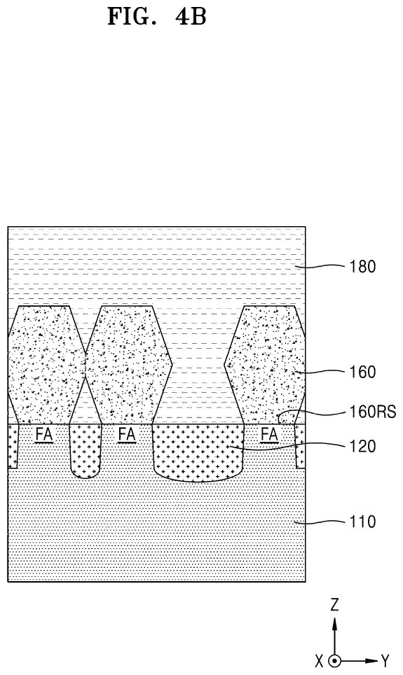

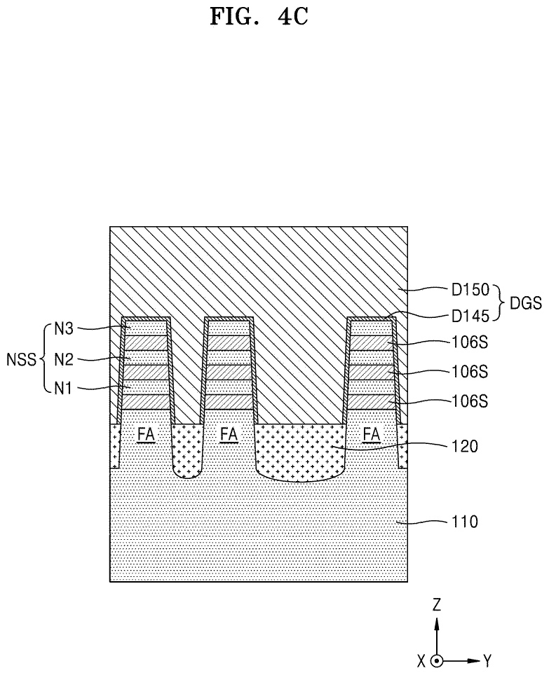

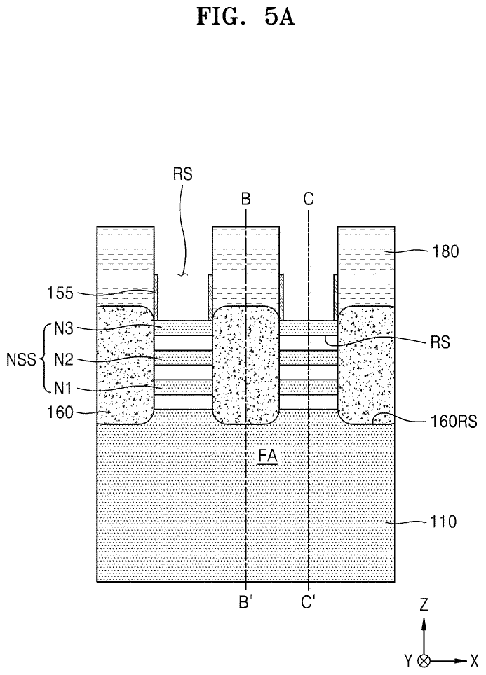

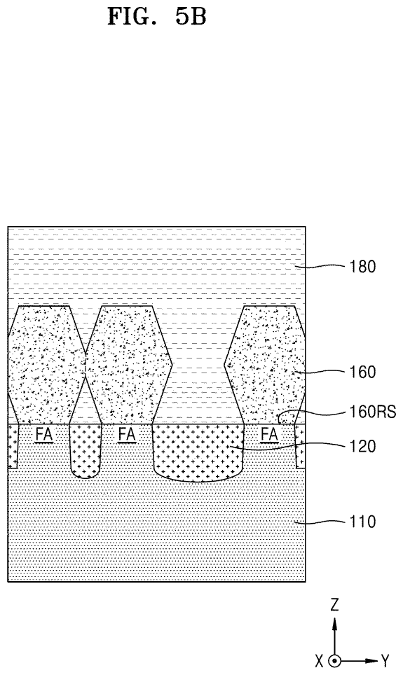

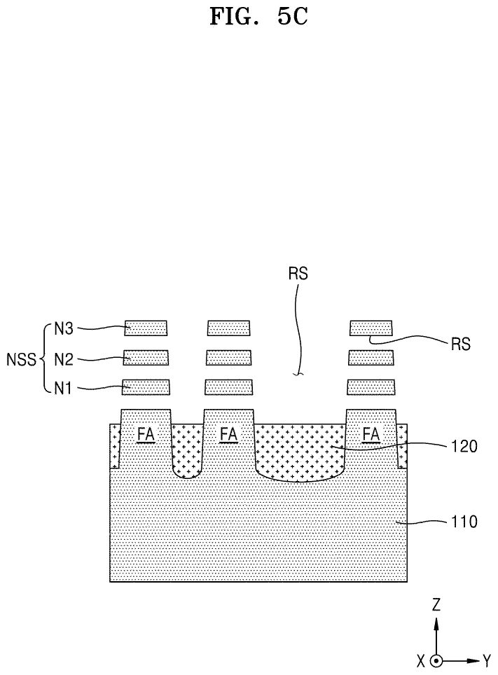

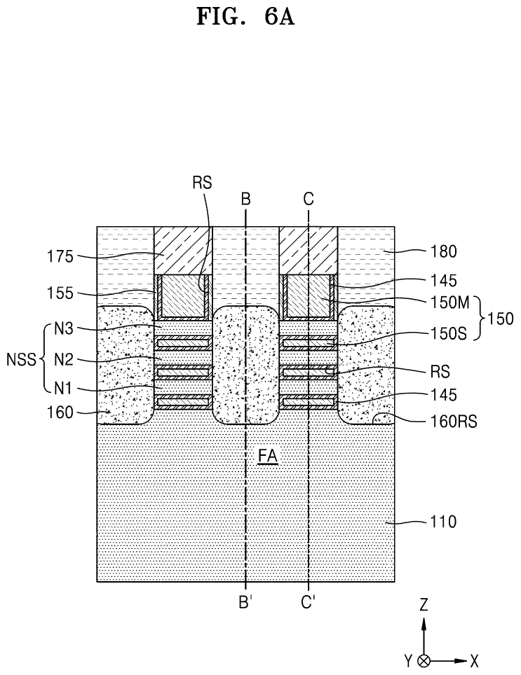

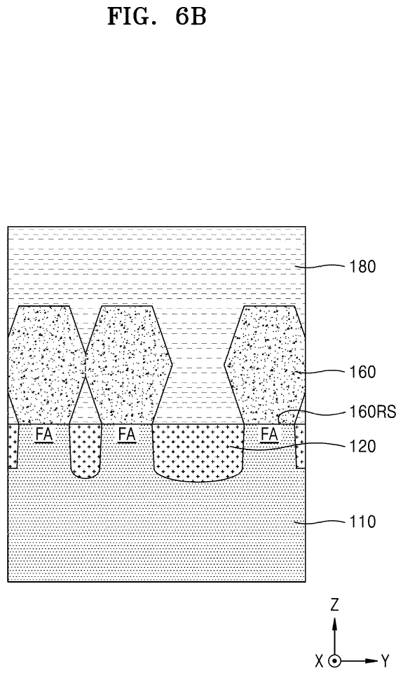

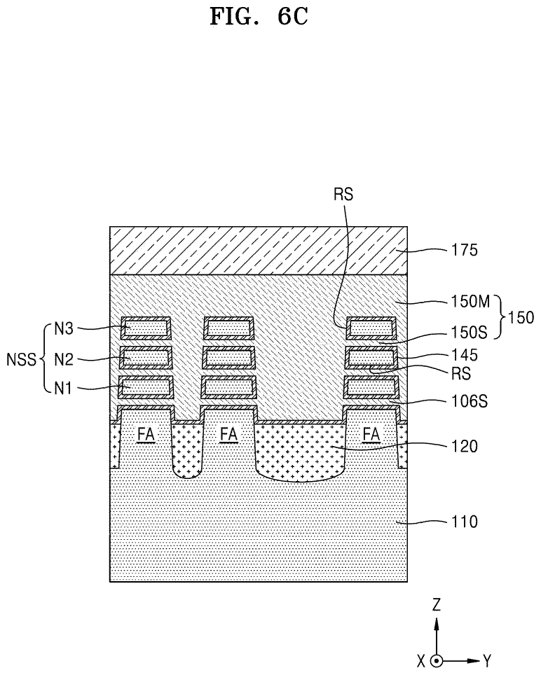

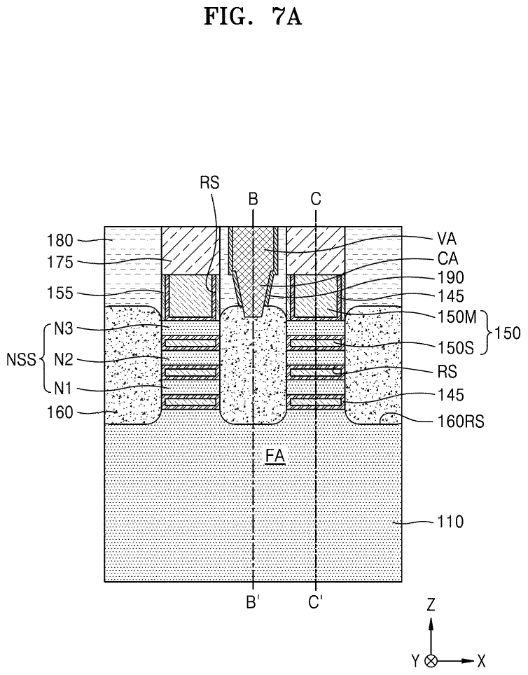

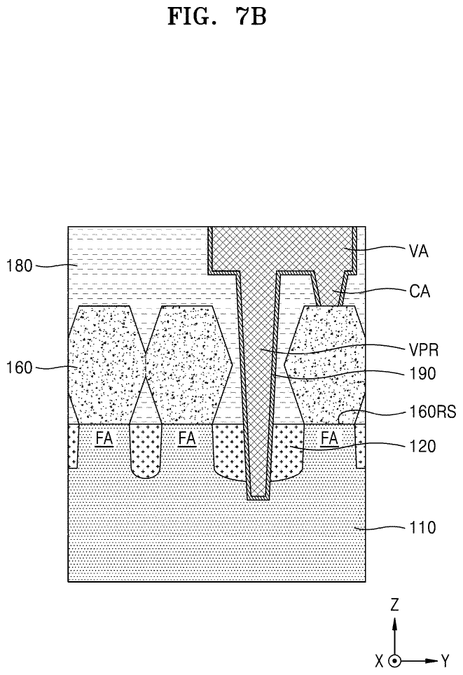

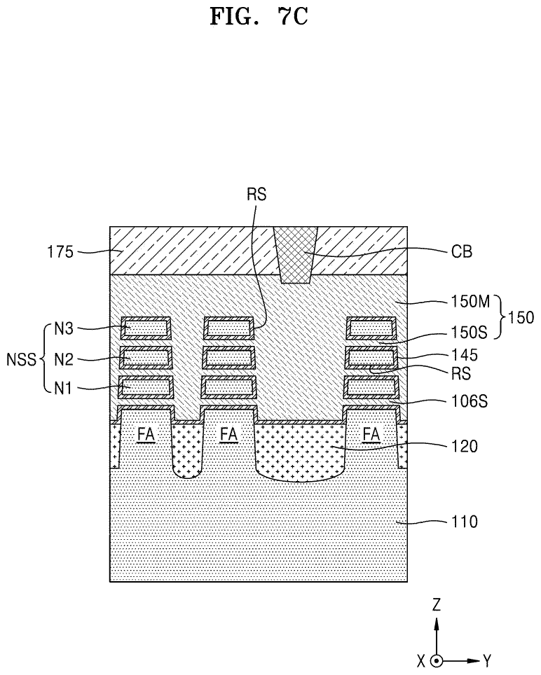

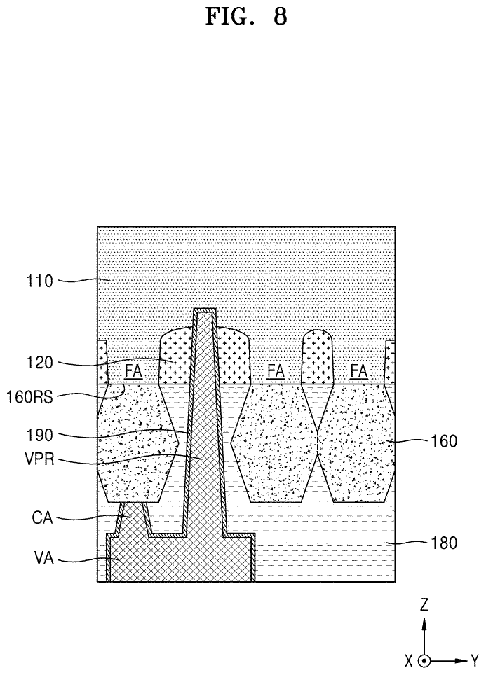

FIGS. 1A to 13 are cross-sectional views of intermediate process stages in an example method of manufacturing an integrated circuit device, according to one or more embodiments. In detail, FIGS. 1B and 1C are cross-sectional views respectively taken along line B-B′ and line C-C′ in FIG. 1A, FIGS. 2B and 2C are cross-sectional views respectively taken along line B-B′ and line C-C′ in FIG. 2A, FIGS. 3B and 3C are cross-sectional views respectively taken along line B-B′ and line C-C′ in FIG. 3A, FIGS. 4B and 4C are cross-sectional views respectively taken along line B-B′ and line C-C′ in FIG. 4A, FIGS. 5B and 5C are cross-sectional views respectively taken along line B-B′ and line C-C′ in FIG. 5A, FIGS. 6B and 6C are cross-sectional views respectively taken along line B-B′ and line C-C′ in FIG. 6A, FIGS. 7B and 7C are cross-sectional views respectively taken along line B-B′ and line C-C′ in FIG. 7A, and FIGS. 8 to 13 are cross-sectional views taken along line B-B′ in FIG. 7A after rotating a position corresponding to line B-B′ in FIG. 7A by 180 degrees.

Referring to FIGS. 1A to 1C, a plurality of sacrificial semiconductor layers 106S and a plurality of nanosheet semiconductor layers are alternately stacked on a substrate 110 in a vertical direction (i.e., Z direction) perpendicular to an upper of the substrate 110. The sacrificial semiconductor layers 106S may include a different semiconductor material than the nanosheet semiconductor layers. In some embodiments, the nanosheet semiconductor layers may be constituted of a single material. In some embodiments, the nanosheet semiconductor layers may include the same material as the substrate 110. In some embodiments, the sacrificial semiconductor layers 106S may include silicon germanium (SiGe) and the nanosheet semiconductor layers may include silicon (Si). However, embodiments are not limited thereto.

The sacrificial semiconductor layers 106S may have the same cross-sectional thickness (in the Z direction) as each other, but embodiments are not limited thereto. In some embodiments, the thickness in the Z direction of a sacrificial semiconductor layer 106S closest to the substrate 110 among the sacrificial semiconductor layers 106S may be greater than the thickness of any other sacrificial semiconductor layers 106S.

The substrate 110 may include a semiconductor material, such as Si or germanium (Ge), or a compound semiconductor material, such as SiGe, silicon carbide (SiC), gallium arsenide (GaAs), indium arsenide (InAs), or indium phosphide (InP). In some embodiments, the substrate 110 may include at least one of a Group III-V material and a Group IV material. The Group III-V materials may include a binary, ternary, or quaternary compound including at least one Group III element and at least one Group V element. In some embodiments, when an n-type metal-oxide semiconductor (NMOS) transistor is formed on a portion of the substrate 110, the portion of the substrate 110 may include one of the Group III-V materials described above. In some embodiments, when a p-type MOS (PMOS) transistor is formed on a portion of the substrate 110, the portion of the substrate 110 may include Ge. Alternatively, the substrate 110 may have a semiconductor-on-insulator (SOI) structure. The substrate 110 may include a conductive region, e.g., an impurity-doped well or an impurity-doped structure.

A plurality of fin-type active regions FA may be formed on the substrate 110 by partially etching a stack structure of the sacrificial semiconductor layers 106S and the nanosheet semiconductor layers and the substrate 110. The fin-type active regions FA may protrude upward in the vertical direction (the Z direction) from the main surface of the substrate 110. In some embodiments, the fin-type active regions FA may extend in a first horizontal direction (X direction) parallel to the upper surface of the substrate 110. In some embodiments, the fin-type active regions FA may have the same width as each other in a second horizontal direction (Y direction) that is perpendicular to the Z direction and intersects the first horizontal direction (the X direction). It is to be appreciated that relational terms, such as, for example, “above,” “below,” “upward,” “downward,” “top,” “bottom,” “horizontal,” “vertical,” and like terms, as may be used throughout the Detailed Description, are intended to be defined relative to a frame of reference, such as, but not limited to, the substrate.

A surface of the substrate 110, in which the fin-type active regions FA are formed, may be referred to as a front side. Herein, the top and bottom surfaces of the substrate 110 or each of the other elements respectively refer to a surface facing upwards and a surface facing downwards in FIGS. 1A to 19B and the front and back sides thereof respectively refer to an active surface, i.e., the surface of the substrate 110, in which the fin-type active regions FA are formed, and an inactive surface of the substrate 110, which is opposite to the active surface of the substrate 110. In FIGS. 1A to 7C, 14A, 14B, 19A, and 19B, the top and bottom surfaces of the substrate 110 may be respectively the front and back sides of the substrate 110. In FIGS. 8 to 13 and 15 to 18, the top and bottom surfaces of the substrate 110 may be respectively the back and front sides of the substrate 110.

The sacrificial semiconductor layers 106S and a stack structure NSS of a plurality of nanosheets N1, N2, and N3 may be on each of the fin-type active regions FA. The stack structure NSS of the nanosheets N1, N2, and N3 may be formed by partially etching the nanosheet semiconductor layers. Although three nanosheets N1, N2, N3 are shown in FIGS. 1A to 1C, embodiments of the inventive concept are not limited thereto.

An isolation film 120 may be formed to fill at least a portion of the space between the fin-type active regions FA. The term “fill” (or “filling,” “filled,” or like terms), as may be used herein, is intended to refer broadly to either completely filling a defined space (e.g., the space between the fin-type active regions FA) or partially filling the defined space; that is, the defined space need not be entirely filled but may, for example, be partially filled or have voids or other spaces throughout. In some embodiments, the isolation film 120 may be formed to fill a lower portion of the space between the fin-type active regions FA. The fin-type active regions FA may protrude from the top surface of the isolation film 120 in the vertical direction (the Z direction). For example, the isolation film 120 may be constituted of a material including at least one selected from the group consisting of a silicon oxide film, a silicon nitride film, and a silicon oxynitride film.

Referring to FIGS. 2A to 2C, a plurality of dummy gate structures DGS may be formed above each of the fin-type active regions FA, on which the stack structure NSS of the nanosheets N1, N2, and N3 and the sacrificial semiconductor layers 106S are formed, to cross at least a portion of each fin-type active region FA. Each of the dummy gate structures DGS may include a dummy insulating film D145 and a dummy gate electrode D150. The dummy gate structures DGS may extend in the second horizontal direction (the Y direction) and may be parallel with each other.

The dummy insulating film D145 and the dummy gate electrode D150 may be sequentially formed to cover the exposed surfaces of the stack structure NSS of the nanosheets N1, N2, and N3 and the sacrificial semiconductor layers 106S, which cover the fin-type active region FA, the exposed surface of the fin-type active region FA, and the top surface of the isolation film 120 and may then be patterned, thereby forming the dummy gate structures DGS. A gate spacer 155 may be formed to cover the side surfaces of each of the dummy gate structures DGS. In some embodiments, the dummy insulating film D145 may include oxide and the dummy gate electrode D150 may include a semiconductor material. However, embodiments are not limited thereto. In some embodiments, the dummy insulating film D145 may include silicon oxide and the dummy gate electrode D150 may include polysilicon. The gate spacer 155 may include, but is not limited to, silicon nitride. The gate spacer 155 may be constituted of a single layer or a stack structure of at least two layers.

Referring to FIGS. 3A to 3C, the stack structure NSS of the nanosheets N1, N2, and N3 and the sacrificial semiconductor layers 106S may be partially removed to form a plurality of source/drain recesses 160RS each exposing a plurality of fin-type active regions FA between two dummy gate structures DGS adjacent to each other in the first horizontal direction (the X direction). In some embodiments, in the process of forming the source/drain recesses 160RS, an upper portion of each of the fin-type active regions FA may also be removed.

Referring to FIGS. 4A to 4C, a plurality of source/drain regions 160 respectively filling the source/drain recesses 160RS may be formed, for example, by epitaxially growing a semiconductor material on the exposed opposite side surfaces of the nanosheets N1, N2, and N3 and the exposed surfaces of the fin-type active regions FA. In some embodiments, when the upper portions of the fin-type active regions FA are removed in the process of forming the source/drain recesses 160RS, the source/drain regions 160 may extend through the top surface of each of the fin-type active regions FA into the inside thereof.

In some embodiments, some of the source/drain regions 160 may include a different material than the other source/drain regions 160; that is, not all of the source/drain regions 160 may be formed of the same material. Some of the source/drain regions 160 and the other source/drain regions 160, which include different materials from each other, may be formed by performing separate epitaxial growth processes. For example, some of the source/drain regions 160 may include Ge. In some embodiments, some of the source/drain regions 160 may have a multi-layer structure of a semiconductor material including Si and a semiconductor material including Ge. For example, the other source/drain regions 160 may include Si but not Ge. In some embodiments, the other source/drain regions 160 may have a multi-layer structure of a semiconductor material including Si and a semiconductor material such as Si or a compound semiconductor material such as SiC.

In some embodiments, a source/drain region 160 in the case of forming an NMOS transistor and a source/drain region 160 in the case of forming a PMOS transistor may include different materials from each other and may be formed by performing separate epitaxial growth processes.

After the source/drain regions 160 are formed, an intergate insulating layer 180 may be formed to cover the source/drain regions 160 and fill spaces between the dummy gate structures DGS. The term “cover” (or “covers,” or like terms), as may be used herein, is intended to broadly refer to an element, structure or layer that is on or over another element, structure or layer, either directly or with one or more other intervening elements, structures or layers therebetween. The intergate insulating layer 180 may fill the spaces between the dummy gate structures DGS and surround (i.e., extend around) the source/drain regions 160. The term “surround” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. The intergate insulating layer 180 may include a silicon oxide film. In some embodiments, the intergate insulating layer 180 may have a stack structure of at least two layers including a first layer constituted of silicon nitride and a second layer constituted of silicon oxide, although embodiments are not limited thereto.

Referring to FIGS. 4A to 4C and 5A to 5C, a plurality of removal spaces RS (i.e., openings) may be formed by removing the dummy gate electrodes D150 and the dummy insulating films D145 and removing the sacrificial semiconductor layers 106S remaining on the fin-type active regions FA. When the dummy gate electrodes D150 and the dummy insulating films D145 are removed, the sacrificial semiconductor layers 106S, which are on the fin-type active regions FA and arranged among the nanosheets N1, N2, and N3, may be exposed and thus removed through spaces resulting from removing the dummy gate electrodes D150 and the dummy insulating films D145. The removal spaces RS may be formed by removing the dummy gate electrodes D150, the dummy insulating films D145, and the sacrificial semiconductor layers 106S.

Referring to FIGS. 6A to 6C, a plurality of gate insulating films 145 may be formed on surfaces exposed in the removal spaces RS, and a plurality of gate electrodes 150 may be formed on the gate insulating films 145 to fill at least some of the removal spaces RS. The gate electrodes 150 may extend in the second horizontal direction (the Y direction) and may be parallel with each other.

Each of the gate insulating films 145 may include, for example, silicon oxide, a high-dielectric constant (high-k) dielectric material, or a combination thereof. For example, each gate insulating film 145 may have a stack structure of an interfacial layer and a high-k dielectric film. In some embodiments, the interfacial layer may include a low-k dielectric layer, e.g., a silicon oxide layer, a silicon oxynitride layer, or a combination thereof, which has a permittivity of about 9 or less. In some embodiments, the interfacial layer may be omitted. The high-k dielectric film may include a material having a higher dielectric constant than silicon oxide. The high-k dielectric film may include metal oxide or metal oxynitride. For example, the high-k dielectric film may have a dielectric constant of about 10 to about 25.

The high-k dielectric film may include hafnium oxide, hafnium oxynitride, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or a combination thereof. However, the materials of the high-k dielectric film are not limited to those above. The high-k dielectric film may be formed by using, for example, atomic layer deposition (ALD), chemical vapor deposition (CVD), or physical vapor deposition (PVD). The high-k dielectric film may have a thickness of about 10 angstroms (Å) to about 40 Å but is not limited thereto.

Each of the gate electrodes 150 may include a work function metal layer and a gap-fill metal layer on the work function metal layer, wherein the gap-fill metal layer fills the removal spaces RS. The work function metal layer may include at least one metal selected from the group consisting of titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). In some embodiment, each gate electrode 150 may have a structure in which a metal nitride layer, a metal layer, a conductive capping layer, and a gap-fill metal film are sequentially stacked. The metal nitride layer and the metal layer may include at least one metal selected from the group consisting of Ti, tantalum (Ta), W, Ru, Nb, Mo, and Hf. The gap-fill metal film may include a tungsten (W) film or an aluminum (Al) film. In some embodiments, the gate electrode 150 may have a stack structure of titanium aluminum carbide (TiAlC)/titanium nitride (TiN)/W, a stack structure of TiN/tantalum nitride (TaN)/TiAlC/TiN/W, or a stack structure of TiN/TaN/TiN/TiAlC/TiN/W but is not limited thereto.

The gate electrode 150 may include a plurality of sub-gate portions 150S, which are formed in the spaces between a fin-type active region FA and the nanosheets N1, N2, and N3, and a main gate portion 150M, which is connected to the sub gate portions 150S and covers the nanosheet stack structure NSS including the nanosheets N1, N2, and N3. The term “connected” (or “connecting,” “contact,” “contacting,” or like terms), as may be used herein, is intended to refer to a physical and/or electrical connection between two or more elements, and may include other intervening elements. As used herein, the term “and/or” includes any and all combinations of one or more of the associated listed items. In some embodiments, an insulating spacer (not shown) may be formed on each of opposite ends of each of the sub gate portions 150S with the gate insulating film 145 between the insulating spacer and each opposite end thereof.

A plurality of gate capping layers 175 may be respectively formed on the plurality of gate electrodes 150. The gate capping layers 175 may respectively cover the gate electrodes 150. The gate capping layers 175 may include nitride. In some embodiments, the top surface of each of the gate capping layers 175 and the top surface of the intergate insulating layer 180 may be at the same level as each other in the vertical direction (the Z direction) and thus be coplanar with each other. For example, the gate insulating films 145, the gate electrodes 150, and the gate capping layers 175 may completely fill the removal spaces RS. For example, the gate insulating films 145 may be formed on the surfaces exposed by the removal spaces RS. Thereafter, the gate electrodes 150 may be formed to fill the removal spaces RS and cover the gate insulating films 145. Thereafter, portions of the gate insulating films 145 and the gate electrodes 150, which fill upper portions of the removal spaces RS, may be removed, and then, the gate capping layers 175 may be formed to fill the upper portions of the removal spaces RS. A plurality of gate electrodes 150, gate capping layers 175, gate insulating films 145, and gate spacers 155, which respectively correspond to one another, may form a plurality of gate structures.

Referring to FIGS. 7A to 7C, a first contact plug CA may be formed to be in contact with and electrically connected to a source/drain region 160 through at least a portion of the intergate insulating layer 180. A second contact plug CB may be formed to be in contact with and electrically connected to a gate electrode 150 through the gate capping layer 175. A via power rail VPR may be formed to extend vertically into the substrate 110 through the isolation film 120. The via power rail VPR may extend into the substrate 110 through a portion of the intergate insulating layer 180 and the isolation film 120. A via contact VA may be formed on the via power rail VPR and electrically connected to the via power rail VPR. The via contact VA may pass through at least a portion of the intergate insulating layer 180.

In some embodiments, the via power rail VPR may extend into a portion of the substrate 110, in which the isolation film 120 is not formed, and thus be separated from the isolation film 120. For example, the via power rail VPR may extend from the via contact VA into the substrate 110 through the intergate insulating layer 180 but not through the isolation film 120.

In some embodiments, each of at least some of the first contact plug CA, the second contact plug CB, the via power rail VPR, and the via contact VA may include a conductive barrier layer and a conductive core layer covering the conductive barrier layer. The conductive barrier layer may include Ti, Ta, TiN, TaN, or a combination thereof. The conductive core layer may include Co, W, copper (Cu), Ru, Ir, Mo, or a combination thereof. However, embodiments are not limited to any specific material(s) forming the conductive barrier and/or the conductive core layer.

A cover insulating layer 190 may be formed to surround the first contact plug CA, the via contact VA, and the via power rail VPR. For example, the cover insulating layer 190 may be between the first contact plug CA and the intergate insulating layer 180 and between the via contact VA and the intergate insulating layer 180. The cover insulating layer 190 may be between the via power rail VPR and each of the intergate insulating layer 180, the isolation film 120, and the substrate 110. In some embodiments, the cover insulating layer 190 may be formed to cover (i.e., on or over) the conductive barrier layer. For example, the conductive barrier layer may be between the conductive core layer and the cover insulating layer 190. The cover insulating layer 190 may include nitride. For example, the cover insulating layer 190 may include silicon nitride. Although it is illustrated in FIG. 7C that the cover insulating layer 190 is not formed around the contact plug CB, this is just an example, and embodiments are not limited thereto. In some embodiments, when the gate capping layer 175, through which the second contact plug CB passes, includes a material (e.g., nitride) that is the same as or similar to a material of the cover insulating layer 190, the cover insulating layer 190 may not be arranged around the second contact plug CB. In some embodiments, when the gate capping layer 175, through which the second contact plug CB passes, includes a material (e.g., oxide) that is different from a material of the cover insulating layer 190, the cover insulating layer 190 may be formed between the second contact plug CB and the gate capping layer 175. In some embodiments, the cover insulating layer 190 may be omitted such that the first contact plug CA and the via contact VA may be in contact with the intergate insulating layer 180 and the via power rail VPR may be in contact with the intergate insulating layer 180, the isolation film 120, and the substrate 110.

Although it is illustrated in FIGS. 7A to 7C that the via contact VA is formed on the first contact plug CA and electrically connected to the first contact plug CA, this is just an example and embodiments are not limited thereto. The via contact VA may be formed on the second contact plug CB and electrically connected to the second contact plug CB. For example, a plurality of via contacts VA may be formed such that some of the via contacts VA may be electrically connected to the first contact plug CA and the other via contacts VA may be electrically connected to the second contact plug CB. The first contact plug CA may be electrically connected to the via power rail VPR through the via contact VA. In some embodiments, the second contact plug CB may also be electrically connected to the via power rail VPR through the via contact VA. Although the case in which the first contact plug CA in FIGS. 7A and 7B is electrically connected to the via power rail VPR through the via contact VA is described below, the descriptions thereof may also be applied to the case in which the second contact plug CB is electrically connected to the via power rail VPR through the via contact VA.

The via contact VA may be formed to extend in the second horizontal direction (the Y direction) from the top surface of the first contact plug CA to the top surface of the via power rail VPR. In some embodiments, at least two of the first contact plug CA, the via contact VA, and the via power rail VPR may be integrally formed together. For example, the first contact plug CA may be integrally formed together with the via contact VA. For example, the via contact VA may be integrally formed together with the via power rail VPR. For example, the first contact plug CA, the via contact VA, and the via power rail VPR may be integrally formed together.

Referring to FIG. 8, the resultant structure of FIGS. 7A to 7C may be rotated 180 degrees such that the substrate 110 faces upwards and the via contact VA faces downwards. The via contact VA and the intergate insulating layer 180 may be attached to a support substrate (not shown).

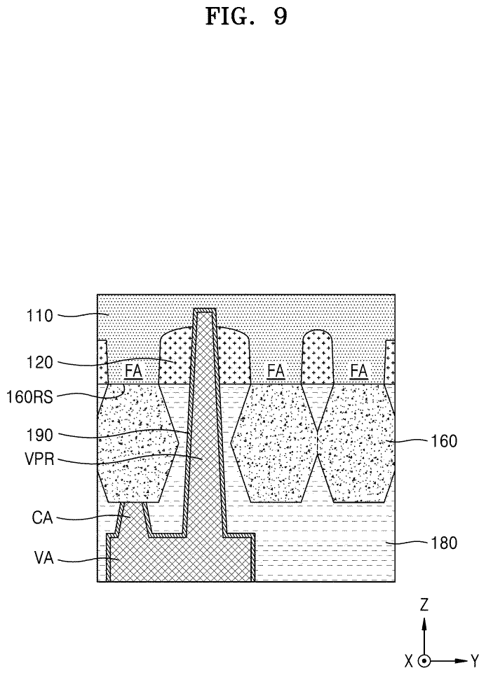

Referring to FIGS. 8 and 9, an upper portion of the substrate 110 may be removed. For example, an upper portion of the substrate 110 may be removed such that the via power rail VPR and the cover insulating layer 190 are not exposed. Accordingly, a cross-sectional thickness of the substrate 110 in the vertical direction (Z direction) may be configured such that a portion of the substrate 110 may remain above the upper end of the via power rail VPR. In some embodiments, when the portion of the substrate 110 above the upper end of the via power rail VPR is relatively thin, the process of removing the upper portion of the substrate 110 may be skipped.

Referring to FIG. 10, a buffer insulating layer 210 may be formed on the top surface of the substrate 110 and a mask pattern 220 may be formed on the buffer insulating layer 210. The buffer insulating layer 210 may include oxide, although embodiments are not limited thereto. For example, the buffer insulating layer 210 may include silicon oxide. For example, the mask pattern 220 may include photoresist.

The mask pattern 220 may include a mask opening PRO. The mask opening PRO may be formed above the via power rail VPR. For example, at least a portion of the mask opening PRO may overlap at least a portion of the via power rail VPR in the vertical direction (the Z direction). The term “overlap” (or “overlapping,” or like terms), as used herein, is intended to broadly refer to a first element that intersects with at least a portion of a second element in the vertical direction (i.e., the Z direction), but does not require that the first and second elements be completely aligned with one another in a horizontal plane (i.e., in the first horizontal direction X and/or the second horizontal direction Y).

The mask pattern 220 may be formed such that a center CPRO of the mask opening PRO according to a top plan view is aligned in the vertical direction (the Z direction) with a center CVPR of the top surface of the via power rail VPR according to a top view. However, when misalignment occurs in the process of forming the mask pattern 220, the center CPRO of the mask opening PRO may not be aligned with the center CVPR of the top surface of the via power rail VPR in the vertical direction (the Z direction).

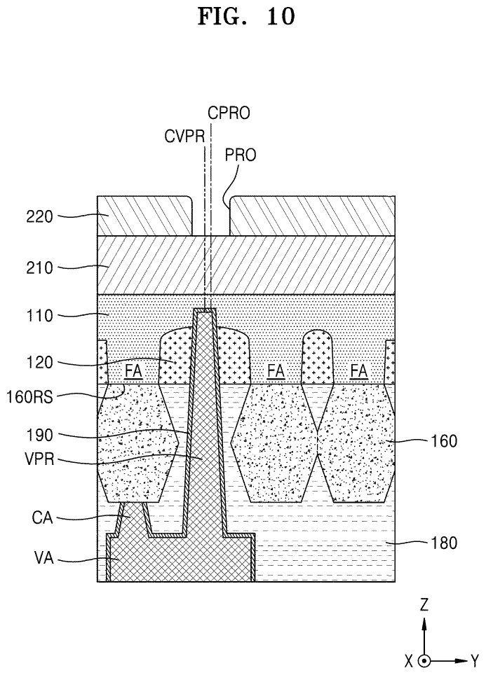

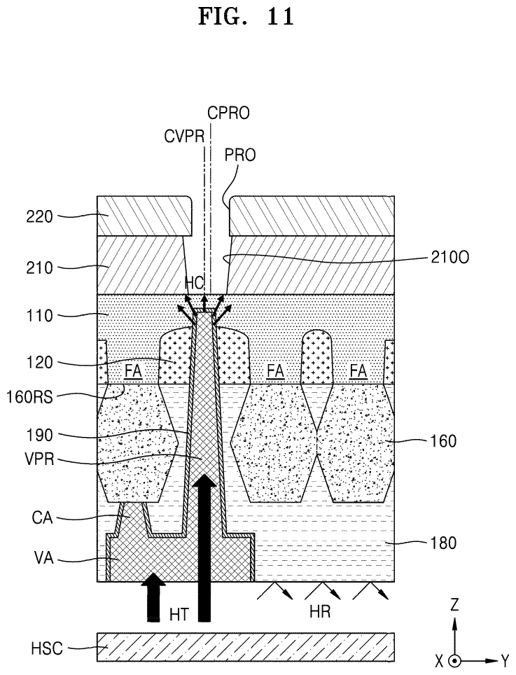

Referring to FIG. 11, a buffer opening 2100 may be formed by etching a portion of the buffer insulating layer 210 by using the mask pattern 220 as an etch mask. The substrate 110 may be exposed at the bottom of the buffer opening 2100. For example, the buffer opening 2100 may be formed by removing a portion of the buffer insulating layer 210 through a wet etching process or a dry etching process.

In the process of forming the buffer opening 2100, a heat source HSC may be provided below the via contact VA and the intergate insulating layer 180. In some embodiments, the heat source HSC may include a laser or an infrared heater. For example, the heat source HSC may correspond to a laser, which generates laser light having a wavelength of about 200 nanometers (nm) to about 1200 nm, or an infrared heater, which generates infrared light having a wavelength of about 750 nm to about 1200 nm. In some embodiments, the heat source HSC may correspond to a laser that generates laser light having a wavelength of about 200 nm to about 800 nm. Heat, e.g., laser light or infrared light, generated by the heat source HSC may be absorbed by a conductive material so that heat transfer HT may occur in the conductive material. However, the heat may not be absorbed by but be reflected from an insulating material so that heat reflection HR instead of the heat transfer HT may occur from the insulating material. For example, the heat transfer HT may occur in the via contact VA including a conductive material but may not occur in the intergate insulating layer 180 including an insulating material. Instead, the heat reflection HR may occur from the intergate insulating layer 180. Heat transferred to the via contact VA may be transferred to the via power rail VPR connected to (i.e., in contact with) the via contact VA.

The heat transferred to the via power rail VPR may induce heat conduction HC in a portion of the substrate 110, which is adjacent to the top end of the via power rail VPR, and a portion of the buffer insulating layer 210, which is on the portion of the substrate 110. The portion of the buffer insulating layer 210 adjacent to the top end of the via power rail VPR may have a higher etch rate than the other portion of the buffer insulating layer 210 because of the heat conducted to the portion of the buffer insulating layer 210. Accordingly, even when the center CPRO of the mask opening PRO does not coincide (i.e., vertically align) with the center CVPR of the top surface of the via power rail VPR in a top plan view due at least in part to misalignment occurring in the process of forming the mask pattern 220, the buffer opening 2100 may be formed such that the center of the buffer opening 2100 in a top plan view is closer to the center CVPR of the top surface of the via power rail VPR than to the center CPRO of the mask opening PRO.

Referring to FIG. 12, a substrate recess 110BO may be formed by etching a portion of the substrate 110 through the buffer opening 2100, using the buffer insulating layer 210 as an etch mask. An upper portion of the via power rail VPR and a portion of the cover insulating layer 190 surrounding the via power rail VPR may be exposed by the substrate recess 110BO. A portion of the isolation film 120, surrounding the via power rail VPR, may be exposed at the bottom of the substrate recess 110BO. For example, the substrate recess 110BO may be formed by removing a portion of the substrate 110 through a wet etching process or a dry etching process.

In the process of forming the substrate recess 110BO, the heat source HSC may be provided below the via contact VA and the intergate insulating layer 180. Heat transferred to the via contact VA may be transferred to the via power rail VPR connected to the via contact VA. The heat transferred to the via power rail VPR may induce the heat conduction HC in a portion of the substrate 110, which is adjacent to the top end of the via power rail VPR. The portion of the substrate 110 adjacent to the top end of the via power rail VPR may have a higher etch rate than the other portion of the substrate 110 because of the heat conducted from the via power rail VPR to the portion of the substrate 110. Accordingly, even when the center CPRO of the mask opening PRO does not coincide with the center CVPR of the top surface of the via power rail VPR in a top plan view because of misalignment occurring in the process of forming the mask pattern 220, the substrate recess 110BO may be formed such that the center of the substrate recess 110BO is vertically aligned with the center CVPR of the top surface of the via power rail VPR according to a top plan view. Accordingly, the substrate recess 110BO may be formed to have a symmetrical structure in the horizontal direction (i.e., the X direction and/or Y direction) with respect to the center CVPR of the top surface of the via power rail VPR.

Referring to FIG. 13, an upper portion of the via power rail VPR may be exposed by etching a portion of the cover insulating layer 190 and a portion of the isolation film 120 through the substrate recess 110BO. The portion of the cover insulating layer 190 and the portion of the isolation film 120 may be removed by a wet etching process or a dry etching process. The substrate recess 110BO may be expanded to a space resulting from the removal of the portion of the cover insulating layer 190 and the portion of the isolation film 120.

In the process of removing the portion of the cover insulating layer 190 and the portion of the isolation film 120, the heat transferred to the via power rail VPR through the via contact VA may induce the heat conduction HC in a portion of the cover insulating layer 190 and a portion of the isolation film 120, which are adjacent to the top end of the via power rail VPR. Due to the heat conducted from the via power rail VPR to the portion of the cover insulating layer 190 and the portion of the isolation film 120, each of the portion of the cover insulating layer 190 and the portion of the isolation film 120, which are adjacent to the top end of the via power rail VPR, may have a higher etch rate than the other portion thereof. Accordingly, the substrate recess 110BO, which is expanded by removing the portion of the cover insulating layer 190 and the portion of the isolation film 120, may be formed to have a symmetrical structure in the horizontal direction with respect to the center CVPR of the top surface of the via power rail VPR.

In some embodiments, when the via power rail VPR is formed to be separated from the isolation film 120, the isolation film 120 through which the via power rail VPR passes in FIG. 13 may be replaced by a portion of the substrate 110 while the shape of the expanded substrate recess 110BO may be substantially the same as that shown in FIG. 13.

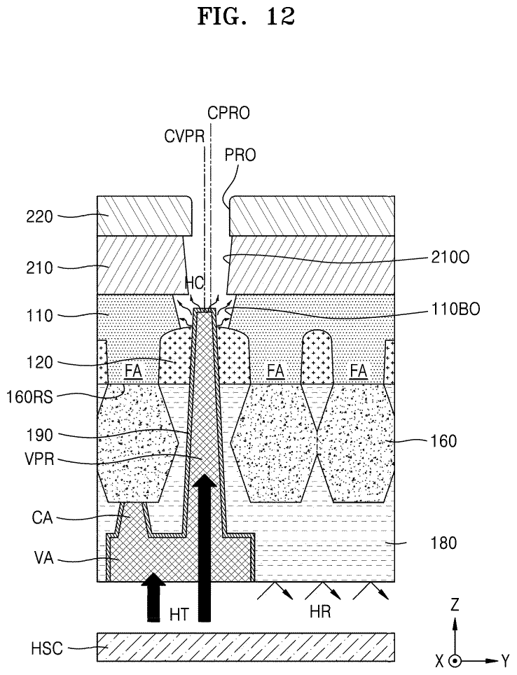

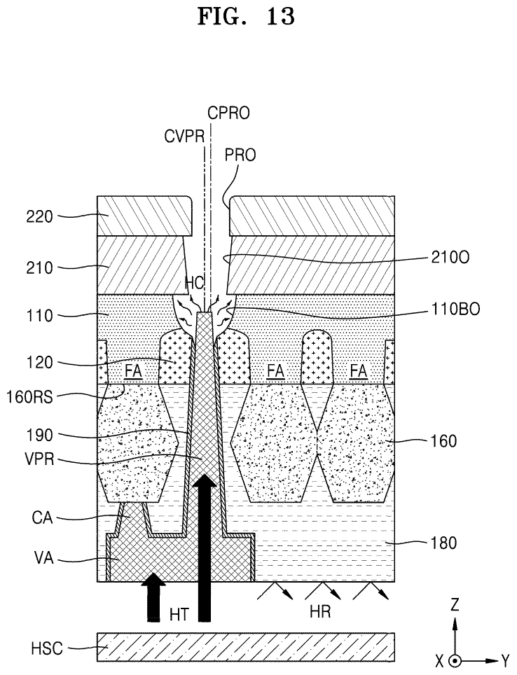

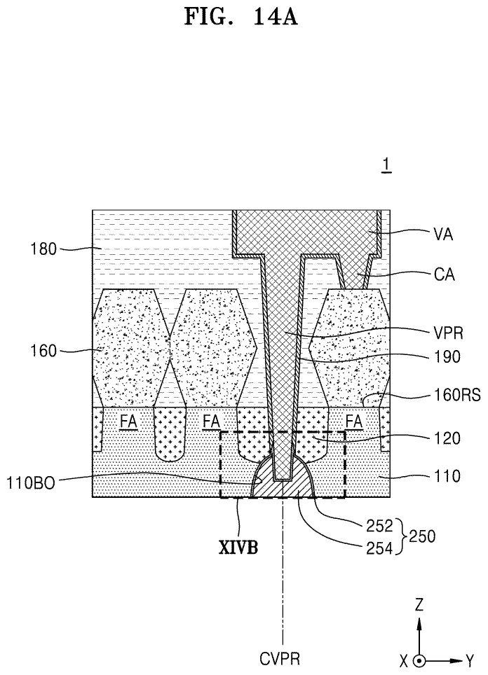

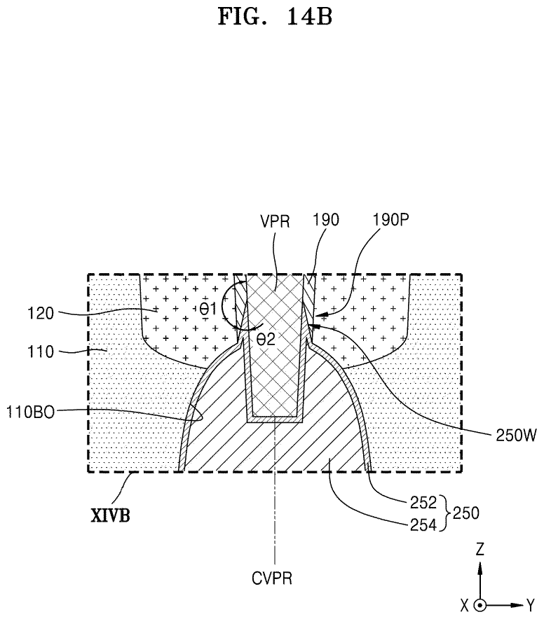

FIGS. 14A and 14B are cross-sectional views of an example integrated circuit device according to one or more embodiments. In detail, FIG. 14A is a cross-sectional view taken along a position corresponding to line B-B′ in FIG. 7A and FIG. 14B is an enlarged view of a region XIVB in FIG. 14A.

Referring to FIGS. 13 to 14B, a backside power rail 250 may be formed to fill the substrate recess 110BO. For example, after the mask pattern 220 is removed, a power rail conductive layer may be formed to fill the substrate recess 110BO and the buffer opening 2100. Thereafter, the substrate 110 may be exposed by removing a portion of the power rail conductive layer and the buffer insulating layer 210, and the backside power rail 250 may be formed to fill the substrate recess 110BO. In some embodiments, the bottom surface of the backside power rail 250 may be coplanar with the bottom surface of the substrate 110 at the same vertical level.

The backside power rail 250 may include a backside conductive barrier layer 252, which covers the exposed surface of the substrate 110 and the exposed surface of the upper portion of the via power rail VPR in the substrate recess 110BO, and a backside conductive core layer 254, which covers the backside conductive barrier layer 252 and fills the substrate recess 110BO. In some embodiments, the backside conductive barrier layer 252 may be formed to conformally cover the exposed surface of the substrate 110 and the exposed surface of the upper portion of the via power rail VPR in the substrate recess 110BO. The backside conductive barrier layer 252 may include, for example, Ti, Ta, TiN, TaN, or a combination thereof and the backside conductive core layer 254 may include, for example, Co, W, Cu, Ru, iridium (Ir), Mo, or a combination thereof, although embodiments are not limited thereto.

Thereafter, a backside wiring layer (not shown) may be formed on the substrate 110 and the backside power rail 250. The resultant structure including the backside wiring layer may be rotated 180 degrees such that the substrate 110 and the backside power rail 250 face downwards and the via contact VA and the intergate insulating layer 180 face upwards, as shown in FIG. 14A. Thereafter, a frontside wiring layer (not shown) may be formed on the via contact VA and the intergate insulating layer 180 so that an integrated circuit device 1 may be formed.

The integrated circuit device 1 may correspond to a logic semiconductor chip. For example, the integrated circuit device 1 may correspond to a central processing unit (CPU) chip, a graphics processing unit (GPU) chip, or an application processor (AP) chip.

Here, the logic semiconductor chip refers to a semiconductor chip that is not a memory semiconductor chip and performs logical operations. For example, the logic semiconductor chip may include a logic cell. In some embodiments, the logic semiconductor chip may include a logic cell and a memory cell. The logic cell may be variously configured to have a plurality of circuit elements, such as a transistor and a register. By way of example only and without limitation, the logic cell may constitute, for example, an AND gate, a NAND gate, an OR gate, a NOR gate, an exclusive OR (XOR) gate, an exclusive NOR (XNOR) gate, an inverter (INV), an adder (ADD), a buffer (BUF), a delay (DLY), a filter (FIL), a multiplexer (MXT/MXIT), an OR/AND/inverter (OAI) gate, an AND/OR (AO) gate, an AND/OR/inverter (AOI) gate, a D flip-flop, a reset flip-flop, a master-slave flip-flop, or a latch. The logic cell may constitute a standard cell, such as a counter, which performs a desired logical function.

Referring to FIGS. 14A and 14B and FIGS. 7A and 7C, the integrated circuit device 1 may include the substrate 110 and a plurality of gate electrodes 150 on the substrate 110. The substrate 110 may include a plurality of fin-type active regions FA on the front side thereof. The fin-type active regions FA protrude in the vertical direction (the Z direction) and extend in the first horizontal direction (the X direction) to be parallel with each other. The gate electrodes 150 extend in the second horizontal direction (the Y direction) that crosses (i.e., intersects) the first horizontal direction (the X direction) and are parallel with each other.

In some embodiments, the integrated circuit device 1 may further include a plurality of nanosheet stack structures NSS, which face and are separated from the top surfaces of the fin-type active regions FA. For example, the integrated circuit device 1 may include a multi-gate metal-oxide semiconductor field-effect transistor (MOSFET) constituted of a fin-type active region FA and a nanosheet stack structure NSS. The fin-type active region FA and the nanoshect stack structure NSS may be collectively referred to as a channel region. The channel region may extend in the first horizontal direction (the X direction). A plurality of gate insulating films 145 may be between the channel region and the gate electrodes 150.

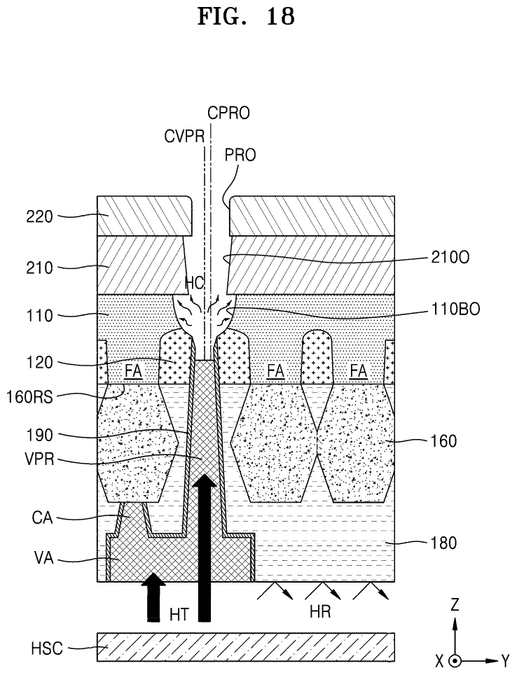

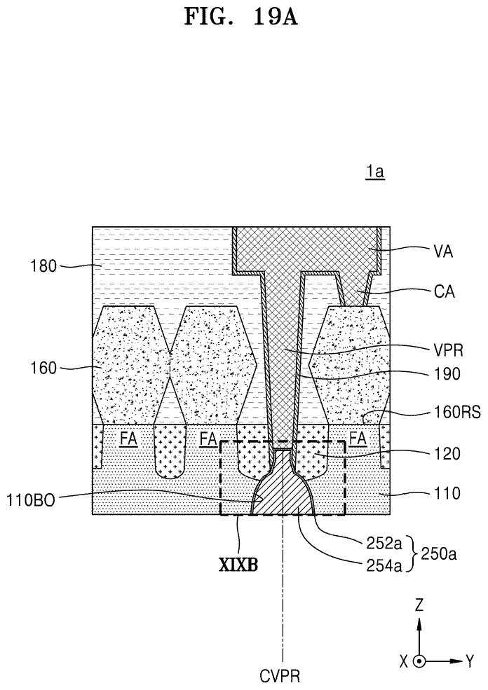

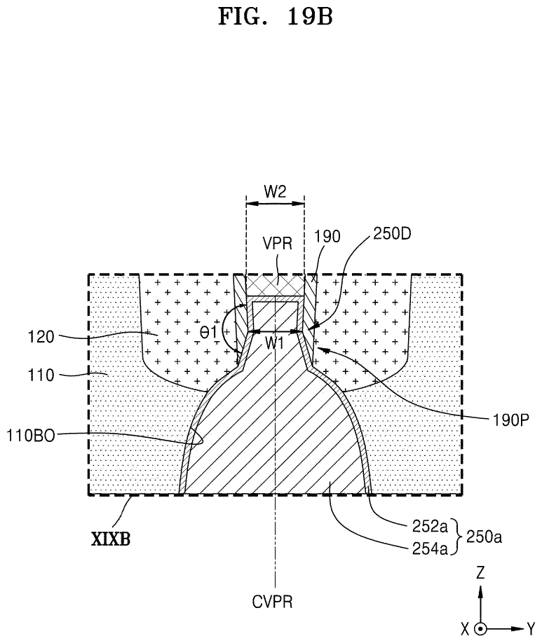

Here, it is described that the integrated circuit device 1 of FIGS. 14A and 14B or an integrated circuit device 1a of FIGS. 19A and 19B includes a multi-gate MOSFET. However, the inventive concept is not limited thereto. For example, it will become apparent to one of skill in the art given the teachings herein that the integrated circuit device 1 of FIGS. 14A and 14B or the integrated circuit device 1a of FIGS. 19A and 19B may include a single-gate MOSFET constituted of a fin-type active region FA instead of a multi-gate MOSFET constituted of a fin-type active region FA and a nanosheet stack structure NSS. When the integrated circuit device 1 of FIGS. 14A and 14B or the integrated circuit device 1a of FIGS. 19A and 19B includes a single-gate MOSFET constituted of a fin-type active region FA instead of a multi-gate MOSFET constituted of a fin-type active region FA and a nanosheet stack structure NSS, the fin-type active region FA may be referred to as a channel region.

The plurality of fin-type active regions FA may be defined by the isolation film 120. The isolation film 120 may fill at least a portion of the space between the fin-type active regions FA. In some embodiments, the isolation film 120 may fill a lower portion of the space between the fin-type active regions FA such that the fin-type active regions FA may protrude from the top surface of the isolation film 120 in the vertical direction (the Z direction). For example, the isolation film 120 may comprise at least one material selected from the group consisting of a silicon oxide film, a silicon nitride film, and a silicon oxynitride film. The isolation film 120 may comprise a single layer including one type of insulating film, a double layer including two types of insulating films, or a multi-layer including at least three types of insulating films. For example, the isolation film 120 may consist of two different types of insulating films. For example, the isolation film 120 may consist of a silicon oxide film and a silicon nitride film. For example, the isolation film 120 may consist of a triple-layer of a silicon oxide film, a silicon nitride film, and a silicon oxide film.

A fin-type active region FA may include a semiconductor, such as Si or Ge, or a compound semiconductor, such as SiGe, SiC, GaAs, InAs, or InP. In some embodiments, the fin-type active region FA may include at least one material selected from the group consisting of Group III-V materials and Group IV materials. The Group III-V materials may include a binary, ternary, or quaternary compound including at least one Group III element and at least one Group V element. In some embodiments, when an NMOS transistor is formed, a plurality of fin-type active regions FA may include one of the Group III-V materials described above. In some embodiments, when a PMOS transistor is formed, the fin-type active regions FA may include Ge.

A plurality of nanosheet stack structures NSS may be separated from the top surfaces of a fin-type active region FA in the vertical direction (the Z direction). The nanosheet stack structures NSS may include a plurality of nanosheets N1, N2, and N3, which extend in parallel with the top surface of the fin-type active region FA.

The nanosheets N1, N2, and N3 constituting a nanosheet stack structure NSS may be sequentially stacked in the vertical direction above the top surface of the fin-type active region FA. Although it is illustrated in the present embodiment that a single nanosheet stack structure NSS includes three nanosheets N1, N2, and N3, the inventive concept is not limited thereto. For example, the nanosheets N1, N2, and N3 may be constituted of a single material. In some embodiments, the nanosheets N1, N2, and N3 may be constituted of the same material as the fin-type active region FA.

A plurality of gate electrodes 150 may be parallel with each other on the fin-type active region FA and may extend in the second horizontal direction (the Y direction) that crosses the first horizontal direction (the X direction). The gate electrodes 150 may at least partially overlap with the fin-type active regions FA and the nanosheet stack structures NSS in the vertical direction (the Z direction).

Each of the gate electrodes 150 may cover a nanosheet stack structure NSS and surround at least some of the nanosheets N1, N2, and N3. Each gate electrode 150 may include a main gate portion 150M, on the top surfaces of the fin-type active region FA and the nanoshect stack structure NSS and the side surface of the nanosheet stack structure NSS, and a plurality of sub-gate portions 150S, which are connected to the main gate portion 150M and formed in the spaces between the fin-type active region FA and the nanosheets N1, N2, and N3, i.e., respectively below the nanosheets N1, N2, and N3. A gate insulating film 145 may be formed between the fin-type active region FA and the gate electrode 150, between the nanosheet stack structure NSS and the gate electrode 150, and between a source/drain region 160 and the gate electrode 150. A plurality of gate capping layers 175 may be respectively on a plurality of gate electrodes 150. The gate capping layers 175 may respectively cover the gate electrodes 150.

A plurality of gate spacers 155 may be on the side surfaces of the gate electrodes 150. In some embodiments, each of the gate spacers 155 may cover the side surfaces of a gate electrode 150 with the gate insulating film 145 between each gate spacer 155 and the gate electrode 150. In some embodiments, a plurality of gate spacers 155 may be on the side surfaces of a plurality of gate electrodes 150 and the side surfaces of a plurality of gate capping layers 175. Although it is illustrated that the topmost end of the gate electrodes 150 is at the same vertical level as (i.e., coplanar with) the topmost end of the gate insulating film 145, embodiments are not limited thereto. In some embodiments, the topmost end of the gate insulating film 145 may be at a higher vertical level than the topmost end of the gate electrode 150 and may be at a vertical level that is the same as or lower than the vertical level of the topmost end of the gate capping layer 175.

In some embodiments, the gate spacer 155 may be on the opposite side surfaces in the first horizontal direction (the X direction) and the opposite side surfaces in the second horizontal direction (the Y direction) of the gate electrode 150 and may completely surround the gate electrode 150 according to a top plan view. The gate electrode 150, the gate capping layer 175, the gate insulating film 145, and the gate spacer 155 may constitute a gate structure.

The gate electrode 150 may be formed by using a replacement metal gate (RMG) process. For example, after a dummy insulating film D145 (in FIGS. 2A and 2C) and a dummy gate electrode D150 (in FIGS. 2A and 2C) are formed on the fin-type active region FA, the gate spacer 155 may be formed to surround the dummy insulating film D145 and the dummy gate electrode D150. Thereafter, the dummy insulating film D145 and the dummy gate electrode D150 may be removed, and the gate insulating film 145 and the gate electrode 150 may be formed in the space surrounded by the gate spacer 155.

A plurality of source/drain regions 160 may be respectively formed on a plurality of fin-type active regions FA. Each of the source/drain regions 160 may be connected to an end of each of the nanosheets N1, N2, and N3 adjacent thereto. Each of the source/drain regions 160 may be formed on a portion of one of a plurality of fin-type active regions FA between a pair of gate electrodes 150 adjacent to each other in the first horizontal direction (the X direction). In some embodiments, each source/drain region 160 may extend through the top surface of a fin-type active region FA into the inside thereof. In some embodiments, the source/drain region 160 may extend through the top surface of the fin-type active region FA into the inside thereof but not to the bottom surface of the substrate 110.

The intergate insulating layer 180 may fill the space between the plurality of gate structures. In some embodiments, the intergate insulating layer 180 may fill the space between the gate structures and surround the plurality of source/drain regions 160.

The first contact plug CA may be electrically connected to a source/drain region 160 through at least a portion of the intergate insulating layer 180. The second contact plug CB may be electrically connected to the gate electrode 150 through the gate capping layer 175. The via contact VA may be electrically connected to the first contact plug CA through at least a portion of the intergate insulating layer 180. The via power rail VPR may extend from the via contact VA through a portion of the intergate insulating layer 180 and the isolation film 120 and may be electrically connected to the backside power rail 250. In some embodiments, when the via power rail VPR is arranged apart from the isolation film 120, the via power rail VPR may extend vertically (i.e., in the Z direction) from the via contact VA through at least a portion of the intergate insulating layer 180 and the substrate 110 and may be electrically connected to the backside power rail 250. The via power rail VPR may protrude from a space defined by the cover insulating layer 190 and extend partially into the backside power rail 250. For example, the side and bottom surfaces of a lower portion of the via power rail VPR may be in contact with the backside power rail 250. The cover insulating layer 190 may surround the first contact plug CA, the via contact VA, and the via power rail VPR. The backside power rail 250 may extend from the back side of the substrate 110 into the substrate 110 to be electrically connected to the via power rail VPR. In some embodiments, the backside power rail 250 may extend from the bottom surface of the substrate 110 into the isolation film 120 through the substrate 110. In some embodiments, the bottom surface of the backside power rail 250 and the backside of the substrate 110 may be at the same vertical level and coplanar with each other.

In some embodiments, each of the first contact plug CA and the second contact plug CB (FIG. 7C) may have a tapered shape having a horizontal width that decreases as the first contact plug CA and the second contact plug CB extend downwards in the vertical direction (the Z direction) toward the substrate 110; that is, the first contact plug CA and the second contact plug CB may be configured having inwardly sloped sidewalls. In some embodiments, the via power rail VPR may have a tapered shape having a horizontal width decreasing downwards in the vertical direction (the Z direction). In some embodiments, the backside power rail 250 may have a tapered shape having a horizontal width increasing downwards in the vertical direction (the Z direction). The backside power rail 250 may have a round (i.e., curved or non-linear) side, which bulges outward toward the substrate 110 and the isolation film 120.

The cover insulating layer 190 may include an insulating protrusion 190P, which extends at the lower end portion of the cover insulating layer 190 and is apart from the via power rail VPR. The insulating protrusion 190P may have a tapered shape having a horizontal width decreasing downwards in the vertical direction (the Z direction). For example, the cover insulating layer 190 may further extend toward the bottom surface of the substrate 110 at a side of the cover insulating layer 190, which is opposite to the via power rail VPR, rather than the other side of the cover insulating layer 190, which is in contact with the via power rail VPR, thereby having the insulating protrusion 190P that is apart from the via power rail VPR.

The backside power rail 250 may include a wedge portion 250W (FIG. 14B) filling a space, which is defined between the via power rail VPR and the insulating protrusion 190P because the cover insulating layer 190 is apart from the via power rail VPR. The wedge portion 250W of the backside power rail 250 may have a tapered shape having a horizontal width decreasing upwards in the vertical direction (the Z direction).

The outer surface of the backside power rail 250, e.g., the outer surface of the wedge portion 250W of the backside power rail 250, may have a first angle θ1 with respect to the side surface of the via power rail VPR and a second angle θ2 with respect to the inner surface of the wedge portion 250W of the backside power rail 250. The first angle θ1 may be obtuse and the second angle θ2 may be acute. In some embodiments, the sum of the first angle θ1 and the second angle θ2 may be 180 degrees.

The backside power rail 250 may have a symmetrical structure in the horizontal direction with respect to the center CVPR of the bottom surface of the via power rail VPR. Although it is illustrated in FIG. 14B that the backside power rail 250 has a symmetrical structure in the second horizontal direction (the Y direction) with respect to the center CVPR of the bottom surface of the via power rail VPR, it will become apparent to one of skill in the art given the teachings herein that the backside power rail 250 may also have a symmetrical structure in the first horizontal direction (the X direction) and in a diagonal (i.e., intersecting) direction relative to the first horizontal direction (the X direction) and the second horizontal direction (the Y direction).

According to the inventive concept, the backside power rail 250 of the integrated circuit device 1 may have a symmetrical structure in the horizontal direction with respect to the center CVPR of the bottom surface of the via power rail VPR, and accordingly, the reliability of electrical connection between the backside power rail 250 and the via power rail VPR may increase. Because the backside power rail 250 of the integrated circuit device 1 includes the wedge portion 250W, the backside power rail 250 may be electrically connected to a lower side surface of the via power rail VPR as well as the bottom surface of the via power rail VPR. Accordingly, the reliability of electrical connection between the backside power rail 250 and the via power rail VPR may increase.

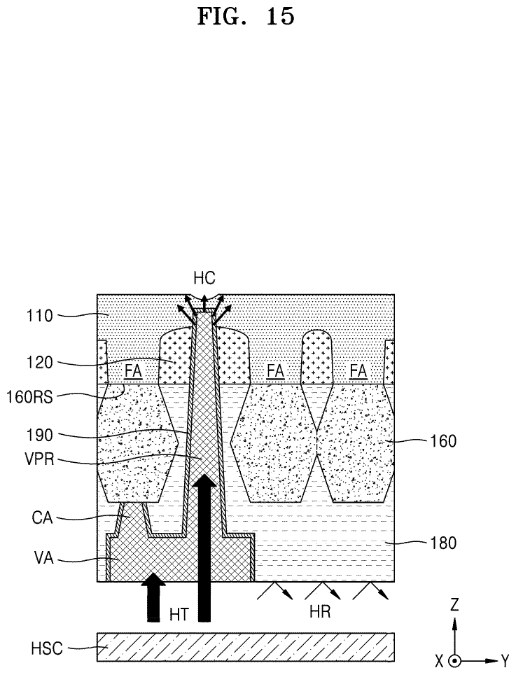

FIGS. 15 to 17 are cross-sectional views illustrating a method of manufacturing an integrated circuit device, according to embodiments. FIGS. 15 to 17 are cross-sectional views taken along line B-B′ in FIG. 7A after rotating the orientation corresponding to line B-B′ in FIG. 7A by 180 degrees.

Referring to FIG. 15, while the heat source HSC is being provided below the via contact VA and the intergate insulating layer 180 in the resultant structure of FIG. 9, an etching process may be performed to remove a portion of the substrate 110. Heat transferred from the heat source HSC to the via contact VA may be transferred to the via power rail VPR connected to the via contact VA. The heat transferred to the via power rail VPR may induce the heat conduction HC in a portion of the substrate 110, which is adjacent to the top end of the via power rail VPR. Due to the heat conducted to the portion of the substrate 110, the portion of the substrate 110, which is adjacent to the top end of the via power rail VPR, may have a higher etch rate than the other portion of the substrate 110 and may thus be removed first.

Referring to FIG. 16, due to the heat conducted to the portion of the substrate 110, the portion of the substrate 110, which is adjacent to the top end of the via power rail VPR, may be removed such that a substrate recess 110BO may be formed. An upper portion of the via power rail VPR and a portion of the cover insulating layer 190 surrounding the via power rail VPR may be exposed by the substrate recess 110BO. The isolation film 120 may be exposed at the bottom of the substrate recess 110BO. For example, the substrate recess 110BO may be formed by removing a portion of the substrate 110 through a wet etching process or a dry etching process.

Referring to FIG. 17, an upper portion of the via power rail VPR may be exposed by etching a portion of the cover insulating layer 190 and a portion of the isolation film 120 through the substrate recess 110BO. The portion of the cover insulating layer 190 and the portion of the isolation film 120 may be removed by a wet etching process or a dry etching process. The substrate recess 110BO may be expanded to a space resulting from the removal of the portion of the cover insulating layer 190 and the portion of the isolation film 120. The substrate recess 110BO, which is expanded by removing the portion of the cover insulating layer 190 and the portion of the isolation film 120, may be formed to have a symmetrical structure in the horizontal direction with respect to a center CVPR of the top surface of the via power rail VPR.

Thereafter, as shown in FIGS. 14A and 14B, the backside power rail 250 may be formed to fill the substrate recess 110BO so that the integrated circuit device 1 may be formed.

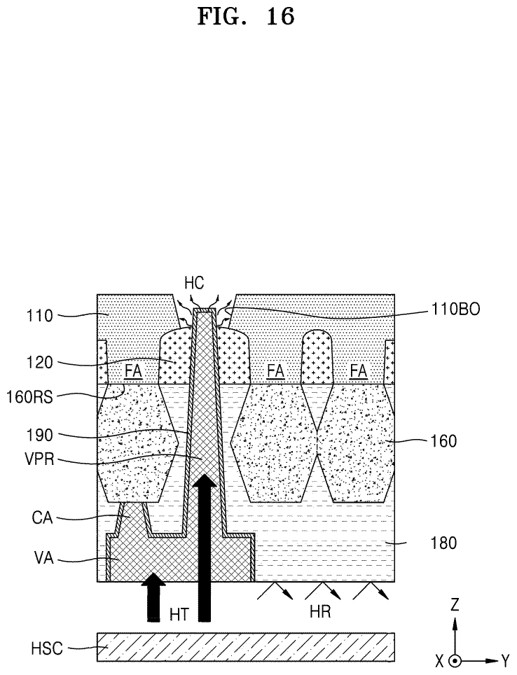

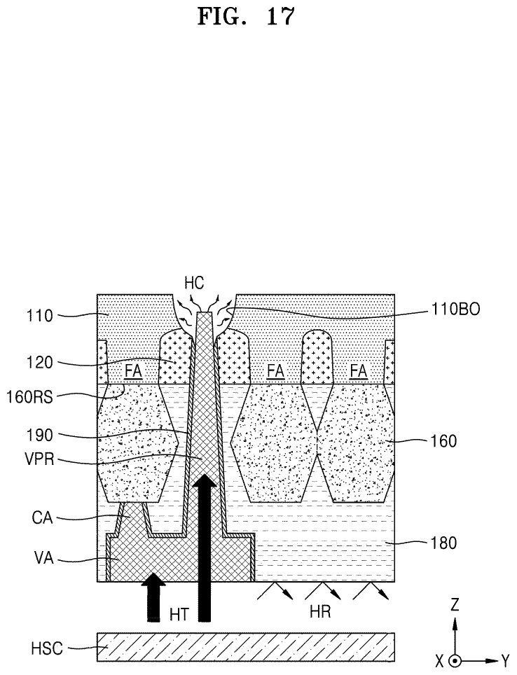

FIG. 18 is a cross-sectional view illustrating an example method of manufacturing an integrated circuit device, according to one or more embodiments. FIG. 18 is a cross-sectional view taken along line B-B′ in FIG. 7A after rotating the orientation corresponding to line B-B′ in FIG. 7A by 180 degrees.

Referring to FIG. 18, an upper portion of the via power rail VPR may be removed through the substrate recess 110BO in the resultant structure of FIG. 13. After the upper portion of the via power rail VPR is removed, the top end of the via power rail VPR may be at a lower vertical level than the top end of the cover insulating layer 190; that is, the top end of the via power rail VPR may be recessed with respect to the top. The substrate recess 110BO may be expanded to a space resulting from the removal of the upper portion of the via power rail VPR. The expanded substrate recess 110BO may include a space defined by the cover insulating layer 190.

FIGS. 19A and 19B are cross-sectional views of an integrated circuit device according to embodiments. In detail, FIG. 19A is a cross-sectional view taken along the position corresponding to line B-B′ in FIG. 7A and FIG. 19B is an enlarged view of a region XIXB in FIG. 19A.

Referring to FIGS. 18 to 19B, a backside power rail 250a may be formed to fill the substrate recess 110BO. For example, after the mask pattern 220 is removed, a power rail conductive layer may be formed to fill the substrate recess 110BO and the buffer opening 2100. Thereafter, the substrate 110 may be exposed by removing a portion of the power rail conductive layer and the buffer insulating layer 210, and the backside power rail 250a may be formed to fill the substrate recess 110BO. The backside power rail 250a may extend to a space defined by the cover insulating layer 190 and may be electrically connected to the via power rail VPR. The backside power rail 250a may include a backside conductive barrier layer 252a, which covers the exposed surface of the substrate 110 and the exposed surface of the upper portion of the via power rail VPR in the substrate recess 110BO, and a backside conductive core layer 254a, which covers the backside conductive barrier layer 252a and fills the substrate recess 110BO.

Thereafter, a backside wiring layer (not shown) may be formed on the substrate 110 and the backside power rail 250a. The resultant structure including the backside wiring layer may be rotated 180 degrees such that the substrate 110 and the backside power rail 250a face downwards and the via contact VA and the intergate insulating layer 180 face upwards. Thereafter, a frontside wiring layer (not shown) may be formed on the via contact VA and the intergate insulating layer 180 so that the integrated circuit device 1a may be formed.

The cover insulating layer 190 may have the insulating protrusion 190P, which further extends toward the bottom surface of the substrate 110 at a side of the cover insulating layer 190, which is opposite to the via power rail VPR, rather than the other side of the cover insulating layer 190, which is in contact with the via power rail VPR. The outer surface of the backside power rail 250a, which is in contact with the insulating protrusion 190P, may have the first angle θ1 with respect to the side surface of the via power rail VPR. The first angle θ1 may be obtuse. The backside power rail 250a may have a first width W1 in the second horizontal direction (Y direction), which is the minimum width in the space defined by the cover insulating layer 190, and a second width W2 in the second horizontal direction (Y direction) at the topmost end thereof, wherein the second width W2 is greater than the first width W1. In other words, the backside power rail 250a may have a backside dent portion 250D, which is at a lower vertical level than the topmost end of the backside power rail 250a and has the first width W1 that is the minimum width in the space defined by the cover insulating layer 190. In some embodiments, in the integrated circuit device 1a, the bottom surface of the backside power rail 250a and the bottom surface of the substrate 110 may be at the same vertical level and coplanar with each other.

While the inventive concept has been particularly shown and described with reference to embodiments thereof, it will be understood that various changes in form and details may be made therein without departing from the spirit and scope of the following claims.

What is claimed is:

1. An integrated circuit device, comprising:
a substrate having a front side and a back side opposite to the front side and including a fin-type active region in the front side and a substrate recess in the back side;
an isolation film in the substrate defining the fin-type active region;
a source/drain region on the fin-type active region;
a contact plug above the substrate;
a backside power rail at least partially filling the substrate recess; and
a via power rail connected to the contact plug, the via power rail extending into the isolation film and connected to the backside power rail,
wherein a side surface of the backside power rail and a side surface of the via power rail form an obtuse angle at a portion where the backside power rail is connected to the via power rail.

2. The integrated circuit device of claim 1, wherein the backside power rail has a symmetrical structure in a horizontal direction parallel to an upper surface of the substrate with respect to a center of a bottom surface of the via power rail.

3. The integrated circuit device of claim 1, wherein the backside power rail includes a curved side surface bulging toward the substrate and the isolation film.

4. The integrated circuit device of claim 1, wherein the contact plug is connected to the source/drain region.

5. The integrated circuit device of claim 1, further comprising a via contact on the contact plug and the via power rail, the via contact connecting the contact plug to the via power rail.

6. The integrated circuit device of claim 1, further comprising
a cover insulating layer extending around the via power rail,
wherein the cover insulating layer includes an insulating protrusion at a bottom end thereof, the insulating protrusion being spaced apart from the via power rail.

7. The integrated circuit device of claim 6, wherein the backside power rail includes a wedge portion at least partially filling a space defined between the via power rail and the insulating protrusion of the cover insulating layer.

8. The integrated circuit device of claim 7, wherein
the insulating protrusion of the cover insulating layer has a tapered shape having a horizontal width that decreases as the insulating protrusion of the cover insulating layer extends vertically towards the substrate, perpendicular to an upper surface of the substrate, and
the wedge portion of the backside power rail has a tapered shape having a horizontal width that decreases as the wedge portion of the backside power rail extends vertically upwards away from the substrate.

9. The integrated circuit device of claim 6, wherein the via power rail extends from a space defined by the cover insulating layer and extends into the backside power rail.

10. The integrated circuit device of claim 6, wherein the backside power rail extends into a space defined by the cover insulating layer and is connected to the via power rail.

11. An integrated circuit device, comprising:
a substrate having a front side and a back side opposite to the front side and including a fin-type active region in the front side and a substrate recess in the back side;
an isolation film in the substrate defining the fin-type active region;
a source/drain region on the fin-type active region;
an intergate insulating layer on the substrate and extending around the source/drain region;
a contact plug extending into at least a portion of the intergate insulating layer and connected to the source/drain region;
a backside power rail at least partially filling the substrate recess;
a via power rail extending into a portion of the intergate insulating layer and the isolation film and connected to the backside power rail; and
a via contact on the contact plug and the via power rail connecting the contact plug to the via power rail,
wherein a side surface of the backside power rail and a side surface of the via power rail form an obtuse angle at a portion where the backside power rail is connected to the via power rail, and
the backside power rail contacts a lower side surface and a bottom surface of the via power rail.

12. The integrated circuit device of claim 11, further comprising
a cover insulating layer extending around the via power rail,
wherein the via power rail protrudes from a space defined by the cover insulating layer and extends into the backside power rail.

13. The integrated circuit device of claim 12, wherein the cover insulating layer includes an insulating protrusion at a bottom end thereof, the insulating protrusion is spaced apart from the via power rail and has a tapered shape having a width in a direction parallel to the front side of the substrate that decreases as the insulating protrusion extends towards the substrate.

14. The integrated circuit device of claim 13, wherein the backside power rail includes a wedge portion at least partially filling a space defined between the via power rail and the insulating protrusion of the cover insulating layer, the wedge portion configured having a tapered shape having a horizontal width that decreases as the wedge portion extends upwards away from the substrate.

15. The integrated circuit device of claim 11, wherein
the via power rail has a tapered shape having a horizontal width that decreases as the via power rail extends downwards towards the substrate, and the backside power rail has a tapered shape having a horizontal width that increases as the backside power rail extends downwards towards the substrate.

16. The integrated circuit device of claim 11, wherein the backside power rail has a symmetrical structure in a horizontal direction with respect to a center of a bottom surface of the via power rail and includes a curved side surface bulging toward the substrate and the isolation film.

17. The integrated circuit device of claim 11, wherein the back side of the substrate and a bottom surface of the backside power rail are coplanar with each other in a vertical direction.

18. An integrated circuit device, comprising:
a substrate having a front side and a back side opposite to the front side and including a fin-type active region in the front side and a substrate recess in the back side, the fin-type active region extending in a first horizontal direction parallel to an upper surface of the substrate;
an isolation film in the substrate defining the fin-type active region;
a backside power rail at least partially filling the substrate recess and including a round side surface bulging toward the substrate and the isolation film;
a plurality of gate electrodes on the fin-type active region and extending in a second horizontal direction in parallel with each other, the second horizontal direction crossing the first horizontal direction parallel to the upper surface of the substrate;
a source/drain region on the fin-type active region and between a pair of gate electrodes, adjacent to each other in the first horizontal direction, among the plurality of gate electrodes;
an intergate insulating layer at least partially filling a space between the plurality of gate electrodes and extending around the source/drain region;
a contact plug extending into at least a portion of the intergate insulating layer and connected to the source/drain region;
a via power rail extending into a portion of the intergate insulating layer and the isolation film and connected to the backside power rail;
a cover insulating layer extending around the via power rail; and
a via contact on the contact plug and the via power rail and connecting the contact plug to the via power rail,
wherein a side surface of the backside power rail and a side surface of the via power rail form an obtuse angle at a portion where the backside power rail is connected to the via power rail, and
the backside power rail includes a wedge portion extending between the via power rail and the cover insulating layer and has a symmetrical structure in the first horizontal direction and/or the second horizontal direction with respect to a center of a bottom surface of the via power rail.

19. The integrated circuit device of claim 18, wherein
the via power rail protrudes from a space defined by the cover insulating layer and extends into the backside power rail, and
the backside power rail is in contact with a lower side surface and the bottom surface of the via power rail.

20. The integrated circuit device of claim 18, wherein
the cover insulating layer includes an insulating protrusion at a bottom end thereof, the insulating protrusion being spaced apart from the via power rail and having a tapered shape having a horizontal width that decreases as the insulating protrusion extends downwards towards the substrate, and
the wedge portion at least partially fills a space defined between the via power rail and the insulating protrusion of the cover insulating layer and has a tapered shape having a horizontal width that decreases as the wedge portion extends upwards away from the substrate.
